(19) United States
(12) Patent Application Publication
(10) Pub. No.: US 2019/0172839 A1
(43) Pub. Date: Jun. 6, 2019

(54) SEMICONDUCTOR DEVICE AND METHOD FOR MANUFACTURING SAME

(71) Applicant: TOSHIBA MEMORY CORPORATION, Minato-ku (JP)

(72) Inventor: Yoshinori TOKUDA, Yokohama (JP)

(73) Assignee: TOSHIBA MEMORY CORPORATION, Minato-ku (JP)

(21) Appl. No.: 16/127,269

(22) Filed: Sep. 11, 2018

(30) Foreign Application Priority Data
Dec. 5, 2017 (JP) 2017-233281

(51) Int. Cl. H01L 27/11582; H01L 27/1157; H01L 29/792

(52) U.S. Cl. CPC H01L 27/11582; H01L 29/7926; H01L 27/1157

(57) ABSTRACT

According to one embodiment, a semiconductor device includes a stacked body, a semiconductor body, and a charge storage portion. The stacked body includes a plurality of electrode layers stacked with an insulator interposed. The semiconductor body extends through the stacked body in a stacking direction of the stacked body. The charge storage portion is provided between the semiconductor body and each of the electrode layers. At least one of the electrode layers is a tungsten film or a molybdenum film including a portion having different fluorine concentration along the stacking direction.

### CROSS-REFERENCE TO RELATED APPLICATION

This application is based upon and claims the benefit of priority from Japanese Patent Application No. 2017-233281, filed on Dec. 5, 2017; the entire contents of which are incorporated herein by reference.

### FIELD

Embodiments described herein relate generally to a semiconductor device and a method for manufacturing a semiconductor device.

### BACKGROUND

A memory device that has a three-dimensional structure has been proposed in which multiple electrode layers are stacked with an insulating layer interposed. As the number of stacks of electrode layers increases, warp due to internal stress of the electrode layers may be caused.

### BRIEF DESCRIPTION OF THE DRAWINGS

FIG. 1 is a schematic perspective view of a semiconductor device according to an embodiment of the invention;

FIG. 2 is a schematic cross-sectional view of the semiconductor device according to the embodiment of the invention;

FIG. 3 is a schematic cross section perspective view of a portion of the semiconductor device according to the embodiment of the invention;

FIG. 4 to FIG. 13B are schematic cross-sectional views showing a method for manufacturing the semiconductor device according to the embodiment of the invention;

FIG. 14A is a graph showing the relationship between a fluorine concentration inside a tungsten film and a lattice constant of a tungsten crystal in an unstrained state of the tungsten film, and FIG. 14B is a graph showing the relationship between a fluorine concentration inside a tungsten film and an internal stress of the tungsten film; and

FIG. 15 is a graph showing the relationship between a nitrogen concentration inside a tungsten film and the internal stress of the tungsten film.

### DETAILED DESCRIPTION

According to one embodiment, a semiconductor device includes a stacked body, a semiconductor body, and a charge storage portion. The stacked body includes a plurality of electrode layers stacked with an insulator interposed. The semiconductor body extends through the stacked body in a stacking direction of the stacked body. The charge storage portion is provided between the semiconductor body and each of the electrode layers. At least one of the electrode layers is a tungsten film or a molybdenum film including a portion having different fluorine concentration along the stacking direction.

Embodiments of the invention will now be described with reference to the drawings. In the drawings, the same components are marked with the same reference numerals; and a detailed description is omitted as appropriate. The drawings are schematic; and the relationships between the thicknesses and widths of portions, the proportions of sizes between portions, etc., are not necessarily the same as the actual values thereof. There are also cases where the dimensions and/or the proportions are illustrated differently between the drawings, even in the case where the same portion is illustrated.

In the embodiment, for example, a semiconductor memory device that includes a memory cell array having a three-dimensional structure is described as a semiconductor device.

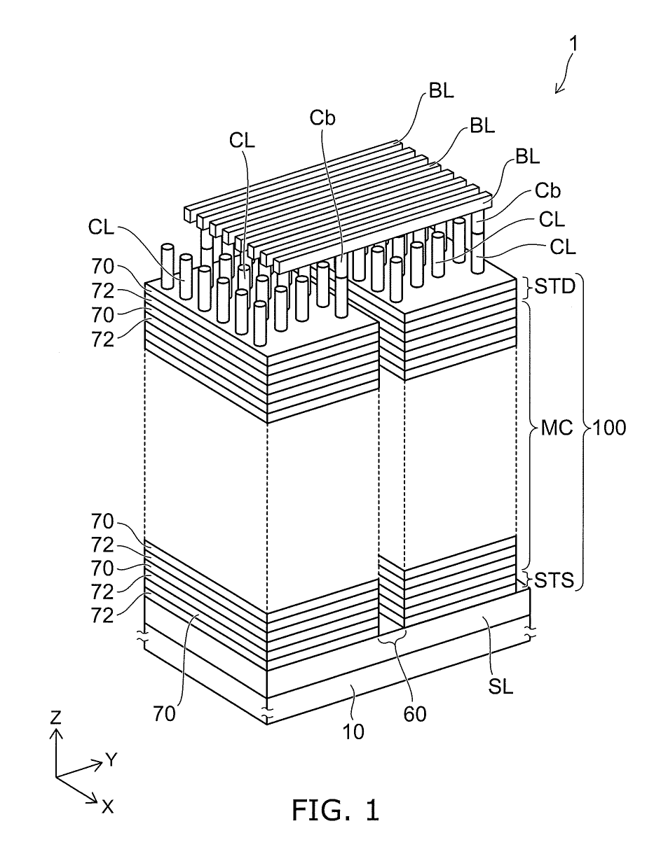

FIG. 1 is a schematic perspective view of the memory cell array 1 according to the embodiment of the invention.

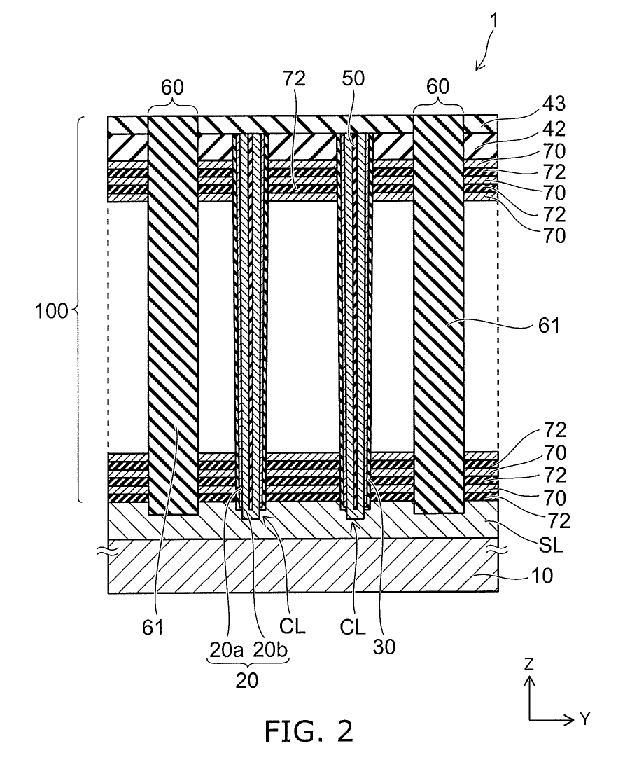

FIG. 2 is a schematic cross-sectional view of the memory cell array 1 according to the embodiment of the invention.

In FIG. 1, two mutually-orthogonal directions parallel to a major surface of a substrate 10 are taken as an X-direction and a Y-direction; and a direction orthogonal to both the X-direction and the Y-direction is taken as a Z-direction (a stacking direction).

The memory cell array 1 includes the substrate 10, a stacked body 100, a source layer SL provided between the substrate 10 and the stacked body 100, multiple columnar portions CL, and multiple bit lines BL provided above the stacked body 100.

The substrate 10 is, for example, a silicon substrate. The source layer SL includes a semiconductor layer doped with an impurity and may further include a layer including a metal. An insulating layer may be provided between the substrate 10 and the source layer SL.

A separation portion 60 is provided in the stacked body 100. The separation portion 60 extends in the stacking direction (the Z-direction) and reaches the source layer SL. The separation portion 60 further extends in the X-direction and divides the stacked body 100 into multiple blocks in the Y-direction. The separation portion 60 is formed from an insulating film 61 as shown in FIG. 2.

The columnar portions CL are formed in substantially circular columnar configurations extending through the stacked body 100 in the stacking direction (the Z-direction). The multiple columnar portions CL have, for example, a staggered arrangement. Or, the multiple columnar portions CL may be arranged in a square lattice along the X-direction and the Y-direction.

The multiple bit lines BL are, for example, metal films extending in the Y-direction. The multiple bit lines BL are separated from each other in the X-direction. The upper end portions of semiconductor bodies 20 of the columnar portions CL described below are connected to the bit lines BL via contacts Cb.

The stacked body 100 includes multiple electrode layers 70 stacked in a direction (the Z-direction) perpendicular to the major surface of the substrate 10. The multiple electrode layers 70 are stacked in the Z-direction with an insulating layer (an insulator) 72 interposed. The insulator between the electrode layers 70 may be an air gap. The insulating layer 72 is provided also between the source layer SL and the lowermost electrode layer 70.

An insulating film 42 is provided on the uppermost electrode layer 70; and an insulating film 43 is provided on the insulating film 42. The insulating film 43 covers the upper ends of the columnar portions CL. The columnar portions CL pierce the multiple electrode layers 70 and the multiple insulating layers 72 and reach the source layer SL.

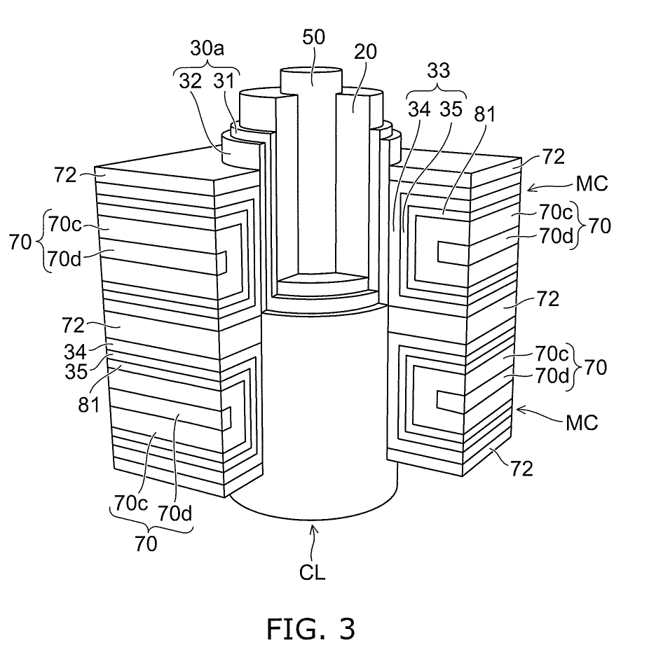

FIG. 3 is a schematic cross-sectional perspective view of portions of the columnar portion CL and the stacked body 100.

The columnar portion CL includes a memory film 30, the semiconductor body 20, and an insulative core film 50. The semiconductor body 20 is formed in a pipe-like configuration; and the core film 50 is provided on the inner side of the semiconductor body 20. The memory film 30 is provided between the semiconductor body 20 and the electrode layer 70, and surrounds the periphery of the semiconductor body 20.

The semiconductor body 20 is, for example, a silicon film; and the lower end portion of the semiconductor body 20 contacts the source layer SL. The upper end portion of the semiconductor body 20 is connected to the bit line BL via the contact Cb shown in FIG. 1.

The memory film 30 is a stacked film including a tunneling insulating film 31, a charge storage film (a charge storage portion) 32, and a blocking insulating film 33. The blocking insulating film 33, the charge storage film 32, and the tunneling insulating film 31 are provided in order from the electrode layer 70 side between the semiconductor body 20 and the electrode layer 70. The tunnel insulating film 31 is provided between the semiconductor body 20 and the charge storage film 32. The charge storage film 32 is provided between the tunnel insulating film 31 and the blocking insulating film 33. The blocking insulating film 33 is provided between the electrode layer 70 and the charge storage film 32.

The semiconductor body 20, the memory film 30, and the electrode layer 70 are included in a memory cell MC. The memory cell MC has a vertical transistor structure in which the electrode layer 70 surrounds the periphery of the semiconductor body 20 with the memory film 30 interposed.

In the memory cell MC having the vertical transistor structure, the semiconductor body 20 functions as a channel; and the electrode layer 70 functions as a control gate. The charge storage film 32 functions as a data storage layer that stores charge injected from the semiconductor body 20.

The semiconductor memory device of the embodiment is a nonvolatile semiconductor memory device that can freely and electrically erase/program data and can retain the memory content even when the power supply is OFF.

The memory cell MC is, for example, a charge trap memory cell. The charge storage film 32 has many trap sites that trap charge inside an insulative film, and includes, for example, a silicon nitride film. Or, the charge storage portion may be a conductive floating gate surrounded with an insulator.

The tunneling insulating film 31 is used as a potential barrier when the charge is injected from the semiconductor body 20 into the charge storage film 32 or when the charge stored in the charge storage film 32 is discharged into the semiconductor body 20. The tunneling insulating film 31 includes, for example, a silicon oxide film. A stacked film 30a that includes the tunneling insulating film 31 and the charge storage film 32 extends to be continuous in the stacking direction of the stacked body 100.

The blocking insulating film 33 prevents the charge stored in the charge storage film 32 from being discharged into the electrode layer 70. Also, the blocking insulating film 33 prevents back-tunneling of the charge from the electrode layer 70 into the columnar portion CL.

The blocking insulating film 33 includes a first blocking film 34 and a second blocking film 35. The first blocking film 34 is a silicon oxide film. The second blocking film 35 is a metal oxide film (e.g., an aluminum oxide film). The first blocking film 34 is provided between the charge storage film 32 and the second blocking film 35; and the second blocking film 35 is provided between the first blocking film 34 and the electrode layer 70.

The blocking insulating film 33 that includes the first blocking film 34 and the second blocking film 35 is provided also between the electrode layer 70 and the insulating layer 72.

The first blocking film 34 is provided between the insulating layer 72 and the second blocking film 35. The second blocking film 35 is provided between the first blocking film 34 and the electrode layer 70.

A barrier metal 81 is provided between the second blocking film 35 and the electrode layer 70. The barrier metal 81 is, for example, a metal nitride film. The barrier metal 81 is, more specifically, a titanium nitride film. The barrier metal 81 prevents the mutual diffusion of the elements between the electrode layer 70 and the blocking insulating film 33.

As shown in FIG. 1, a drain-side select transistor STD is provided in the upper layer portion of the stacked body 100; and a source-side select transistor STS is provided in the lower layer portion of the stacked body 100.

Among the multiple electrode layers 70, at least the uppermost electrode layer 70 may function as a control gate of the drain-side select transistor STD; and at least the lowermost electrode layer 70 may function as a control gate of the source-side select transistor STS.

The multiple memory cells MC are provided between the drain-side select transistor STD and the source-side select transistor STS. The multiple memory cells MC, the drain-side select transistor STD, and the source-side select transistor STS are connected in series via the semiconductor body 20 of the columnar portion CL. The multiple memory cells MC are provided three-dimensionally in the X-direction, the Y-direction, and the Z-direction.

In the example shown in FIG. 3, the electrode layer 70 includes a first conductive film 70c and a second conductive film 70d. The first conductive film 70c is provided at the surface of the barrier metal 81; and the second conductive film 70d is provided on the inner side of the first conductive film 70c. The first conductive film 70c is provided between the second conductive film 70d and the barrier metal 81. The barrier metal 81 functions as a foundation film of the crystal growth of the first conductive film 70c.

The first conductive film 70c and the second conductive film 70d are tungsten films. Or, the first conductive film 70c and the second conductive film 70d are molybdenum films.

The lattice constant of the tungsten crystal of the first conductive film 70c and the lattice constant of the tungsten crystal of the second conductive film 70d are different in the unstrained state. Or, the lattice constant of the molybdenum crystal of the first conductive film 70c and the lattice constant of the molybdenum crystal of the second conductive film 70d are different in the unstrained state.

For example, the analysis and the detection of the lattice constant are possible using XRD (X-ray diffraction), a TEM (transmission electron microscope), or a SEM (scanning electron microscope). Then, it is possible to estimate the value of the internal stress from the lattice constant.

The internal stress of the first conductive film 70c and the internal stress of the second conductive film 70d are different due to such a lattice constant difference. Here, the internal stress being different means that the magnitude (the absolute value) of the internal stress is different. Or, the internal stress being different means that the direction of the internal stress is different. In other words, the magnitude of the internal stress of the first conductive film 70c and the magnitude of the internal stress of the second conductive film 70d are different. Or, the first conductive film 70c has tensile stress; and the second conductive film 70d has compressive stress. Or, the first conductive film 70c has compressive stress; and the second conductive film 70d has tensile stress.

For example, the first conductive film 70c and the second conductive film 70d which are both metal films include a non-metallic element; and the concentration of the non-metallic element inside the first conductive film 70c and the concentration of the non-metallic element inside the second conductive film 70d are different. Such a non-metallic element concentration difference causes the internal stress of the first conductive film 70c and the internal stress of the second conductive film 70d to be different.

For example, the fluorine concentration in the first conductive film 70c which is a tungsten film or a molybdenum film and the fluorine concentration in the second conductive film 70d which is a tungsten film or a molybdenum film are different.

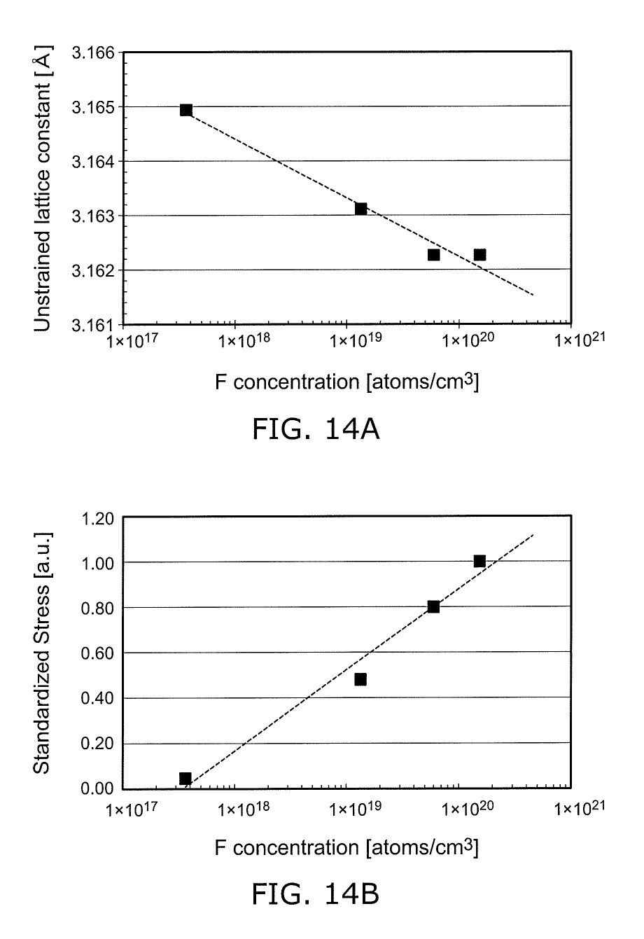

FIG. 14A is a graph (experimental results) illustrating the relationship between the fluorine concentration (the average concentration) inside the tungsten film and the lattice constant of the tungsten crystal in the unstrained state of the tungsten film.

FIG. 14B is a graph (experimental results) illustrating the relationship between the fluorine concentration (the average concentration) inside the tungsten film and the internal stress (the tensile stress) of the tungsten film.

Results similar to the results shown in FIGS. 14A and 14B are obtained also for molybdenum which has a crystal structure similar to that of tungsten.

From the results of FIG. 14A, it can be confirmed that the crystal lattice of tungsten contracts as the fluorine concentration increases.

From the results of FIG. 14B, it can be confirmed that the tensile stress of the tungsten film increases as the fluorine concentration increases.

It is considered that the increase of the fluorine concentration causes the crystal lattice of the tungsten to contract; the lattice misfit between the tungsten film and the foundation film increases due to the contraction of the crystal lattice of the tungsten; and the tensile stress of the tungsten film increases.

As shown in FIG. 14B, it can be confirmed that the tensile stress of the tungsten film changes according to the fluorine concentration in the range where the fluorine concentration in the tungsten film is not less than 2×10¹⁷ (atoms/cm³) and not more than 1.5×10²⁰ (atoms/cm³). Accordingly, the magnitude of the tensile stress of the first conductive film 70c can be controlled by controlling the fluorine concentration in the first conductive film 70c to be within the range not less than 2×10¹⁷ (atoms/cm³) and not more than 1.5×10²⁰ (atoms/cm³). Similarly, the magnitude of the tensile stress of the second conductive film 70d can be controlled by controlling the fluorine concentration in the second conductive film 70d to be within the range not less than 2×10¹⁷ (atoms/cm³) and not more than 1.5×10²⁰ (atoms/cm³).

Or, the nitrogen concentration in the first conductive film 70c which is a tungsten layer or a molybdenum layer and the nitrogen concentration in the second conductive film 70d which is a tungsten layer or a molybdenum layer are different.

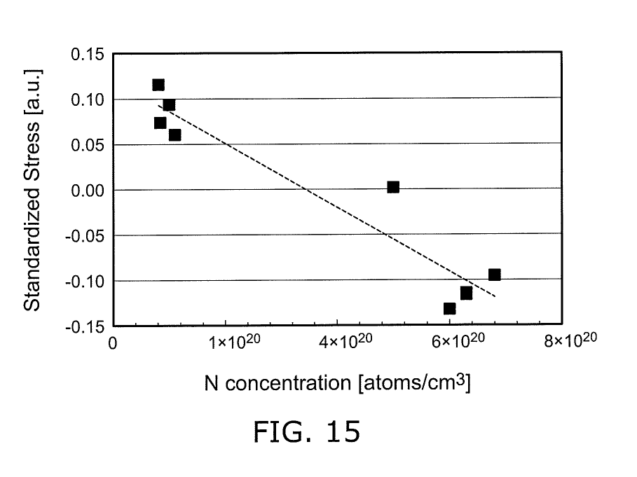

FIG. 15 is a graph (experimental results) illustrating the relationship between the nitrogen concentration (the average concentration) inside the tungsten film and the internal stress of the tungsten film. For the vertical axis, a positive numerical value illustrates the magnitude of the tensile stress; and a negative numerical value illustrates the magnitude of the compressive stress.

Results similar to the results shown in FIG. 15 are obtained also for molybdenum which has a crystal structure similar to that of tungsten.

From the results of FIG. 15, it can be confirmed that the compressive stress of the tungsten film increases as the nitrogen concentration increases.

It is considered that the increase of the nitrogen concentration in the tungsten film causes lattice expansion of the tungsten crystal; and the compressive stress of the tungsten film increases.

Or, the carbon concentration in the first conductive film 70c which is a tungsten layer or a molybdenum layer and the carbon concentration in the second conductive film 70d which is a tungsten layer or a molybdenum layer are different.

It can be confirmed that the compressive stress of the tungsten film increases as the carbon concentration increases.

Or, the oxygen concentration in the first conductive film 70c which is a tungsten layer or a molybdenum layer and the oxygen concentration in the second conductive film 70d which is a tungsten layer or a molybdenum layer are different.

It can be confirmed that the compressive stress of the tungsten film increases as the oxygen concentration increases.

The electronegativity of tungsten (W) is 1.7; and the electronegativity of fluorine (F) is 4.0. It is considered that there is a tendency for tensile stress to be generated in the tungsten film due to such an electronegativity difference between tungsten and fluorine.

Conversely, the electronegativity of nitrogen (N) is 3.0; the electronegativity of carbon (C) is 2.5; and the electronegativity of oxygen (O) is 3.5. It is considered that there is a tendency for compressive stress to be generated in the tungsten film by adding, to the tungsten film, at least one of nitrogen, carbon, or oxygen having electronegativities smaller than that of fluorine.

The warp of the wafer including the stacked body 100 can be suppressed by forming the first conductive film 70c and the second conductive film 70d which has different internal stresses each other, inside the electrode layer 70. For example, when one of the first conductive film 70c or the second conductive film 70d has tensile stress and the other has compressive stress, the tensile stress and the compressive stress cancel; and the warp of the wafer can be suppressed.

The electrical resistance of the electrode layer 70 decreases as the concentration of the non-metallic element described above (fluorine, nitrogen, carbon, and oxygen) added to the electrode layer 70 which is a metal layer decreases. For example, the concentration of the non-metallic element inside the first conductive film 70c is suppressed to reduce the resistance. In the case where the first conductive film 70c has tensile stress, the warp of the wafer can be suppressed by causing the second conductive film 70d to have compressive stress that reduces or cancels the tensile stress of the first conductive film 70c by adding at least one of nitrogen, carbon, or oxygen to the second conductive film 70d. In such a case, the greater part of one layer of the electrode layers 70 may be the first conductive film 70c having the lower resistance; and the volume of the second conductive film 70d may be smaller than the volume of the first conductive film 70c.

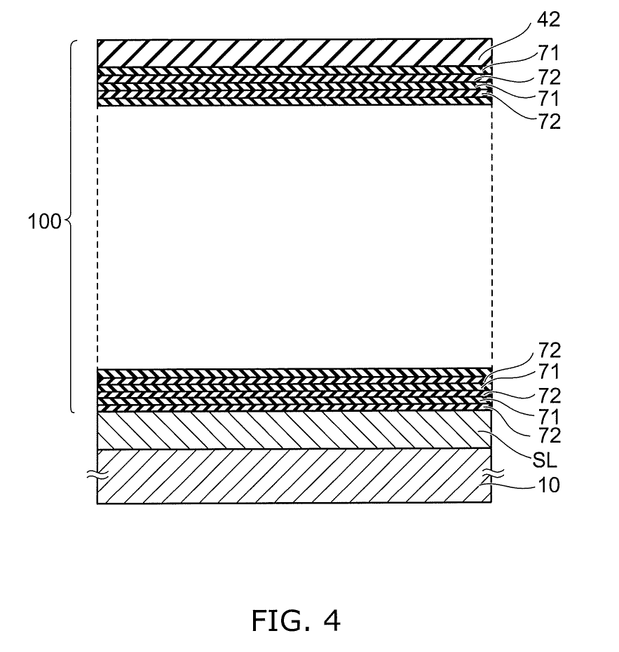

A method for manufacturing the semiconductor device shown in FIG. 3 will now be described with reference to FIG. 4 to FIG. 13B.

As shown in FIG. 4, the source layer SL is formed on the substrate 10; and the stacked body 100 that includes multiple sacrificial layers (the first layers) 71 and the multiple insulating layers (the second layers) 72 is formed on the source layer SL. For example, the sacrificial layers 71 are silicon nitride layers; and the insulating layers 72 are silicon oxide layers.

The insulating layer 72 is formed on the surface of the source layer SL; and the sacrificial layer 71 is formed on the insulating layer 72. Thereafter, the processes of alternately stacking the insulating layer 72 and the sacrificial layer 71 are repeated. The insulating film 42 is formed on the uppermost sacrificial layer 71.

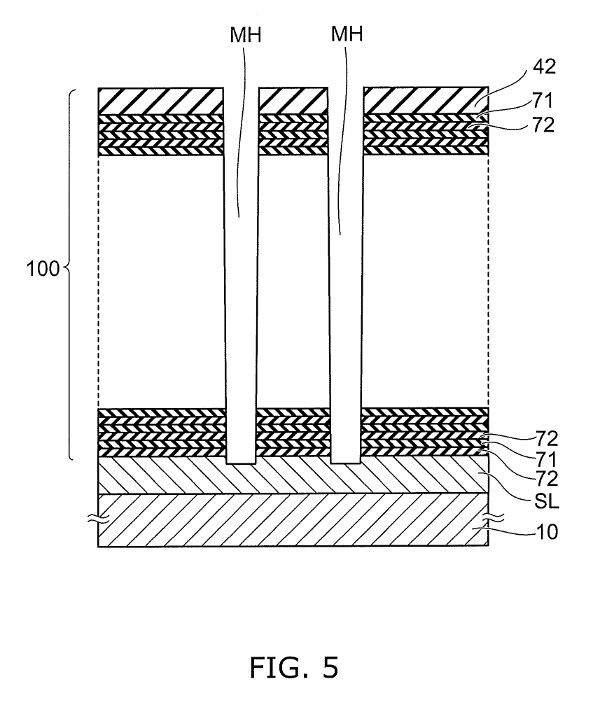

As shown in FIG. 5, multiple memory holes MH are formed in the stacked body 100. The memory holes MH are formed by RIE (reactive ion etching) using a not-illustrated mask. The memory holes MH pierce the stacked body 100 and reach the source layer SL.

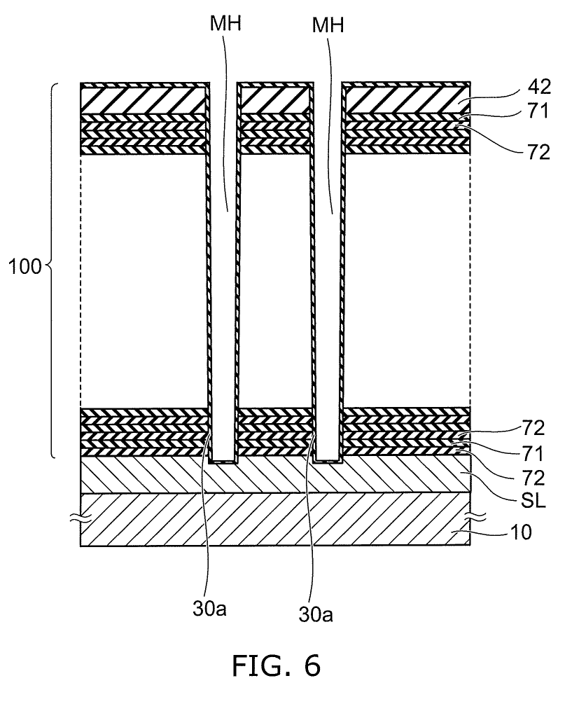

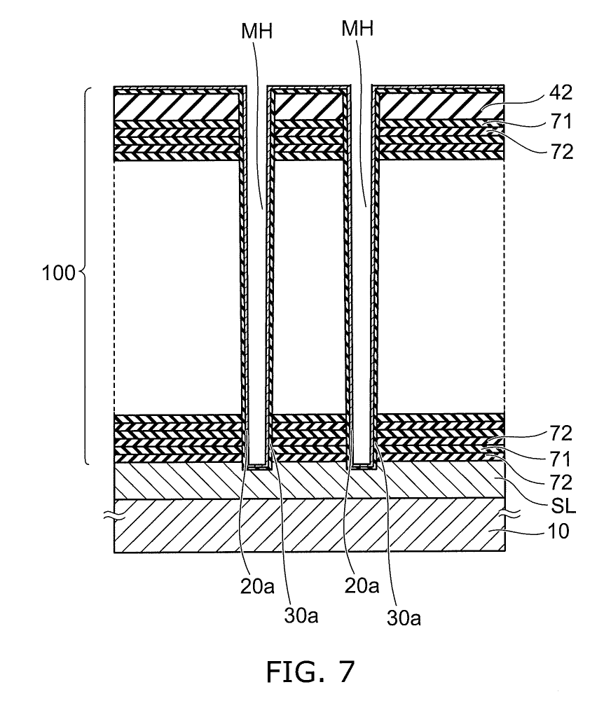

As shown in FIG. 6, the stacked film 30a is formed conformally on the side surfaces and the bottom surfaces of the memory holes MH. The stacked film 30a includes the tunneling insulating film 31 and the charge storage film 32 shown in FIG. 3. As shown in FIG. 7, a cover silicon film 20a is formed conformally on the inner side of the stacked film 30a.

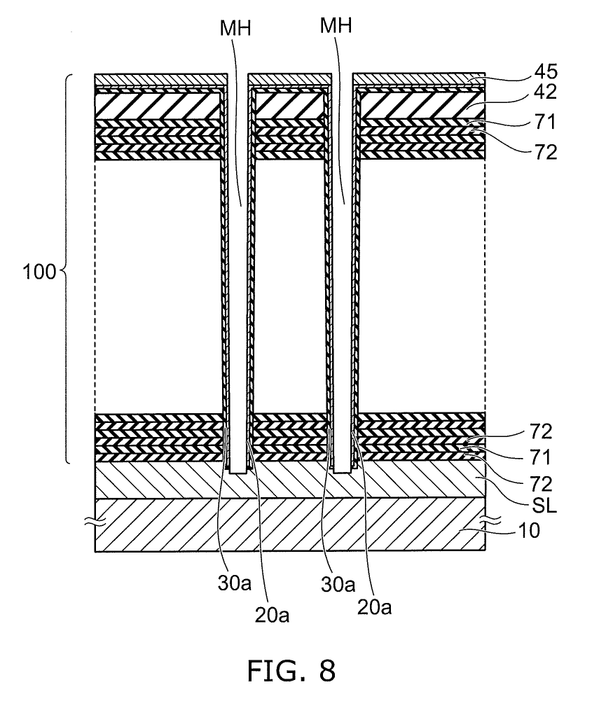

Subsequently, as shown in FIG. 8, a mask layer 45 is formed on the stacked body 100; and the cover silicon film 20a and the stacked film 30a that are formed on the bottom surfaces of the memory holes MH are removed by RIE. In the RIE, the stacked film 30a formed on the side surfaces of the memory holes MH is protected by being covered with the cover silicon film 20a. The stacked film 30a formed on the side surfaces of the memory holes MH is not damaged by the RIE.

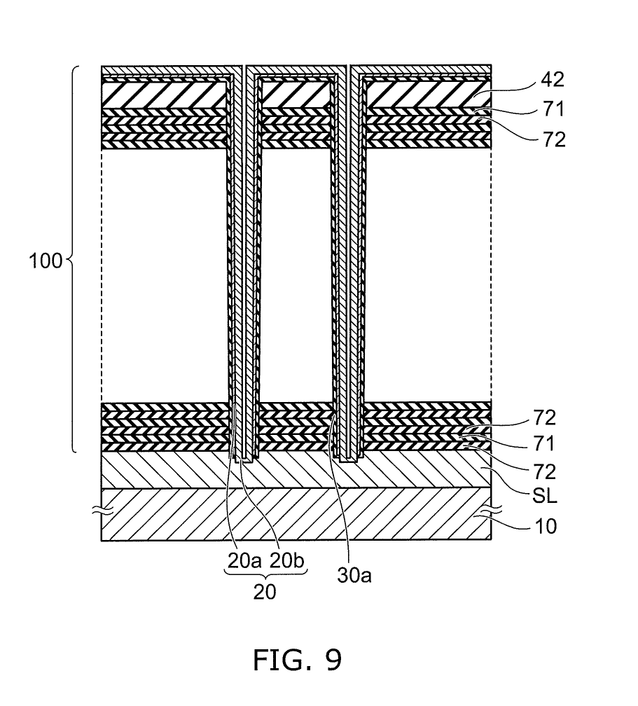

After removing the mask layer 45, a semiconductor film (a silicon film) 20b is formed inside the memory holes MH as shown in FIG. 9. The semiconductor film 20b is formed on the side surface of the cover silicon film 20a and the bottom surfaces of the memory holes MH where the source layer SL is exposed.

For example, after the cover silicon film 20a and the semiconductor film 20b are formed as amorphous silicon films, the cover silicon film 20a and the semiconductor film 20b are crystallized into polycrystalline silicon films by heat treatment. The cover silicon film 20a and the semiconductor film 20b are included in the semiconductor body 20 described above.

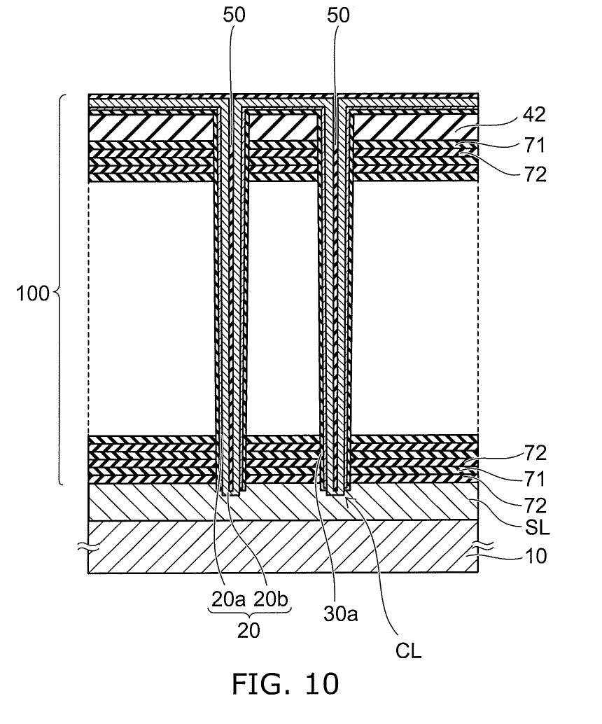

As shown in FIG. 10, the core film 50 is formed on the inner side of the semiconductor film 20b. Thus, the columnar portion CL that includes the stacked film 30a, the semiconductor body 20, and the core film 50 is formed.

The films deposited on the insulating film 42 shown in FIG. 10 are removed by CMP (chemical mechanical polishing) or etch-back.

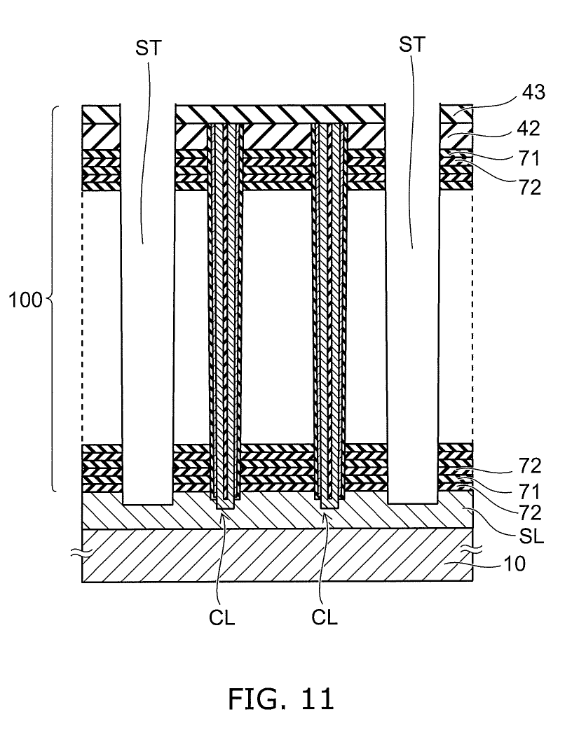

Subsequently, as shown in FIG. 11, the insulating film 43 is formed on the insulating film 42. The insulating film 43 covers the upper ends of the columnar portions CL. Then, multiple slits ST are formed in the stacked body 100 including the insulating film 43, the insulating film 42, the multiple sacrificial layers 71, and the multiple insulating layers 72 by RIE using a not-illustrated mask. The slits ST pierce the stacked body 100 and reach the source layer SL.

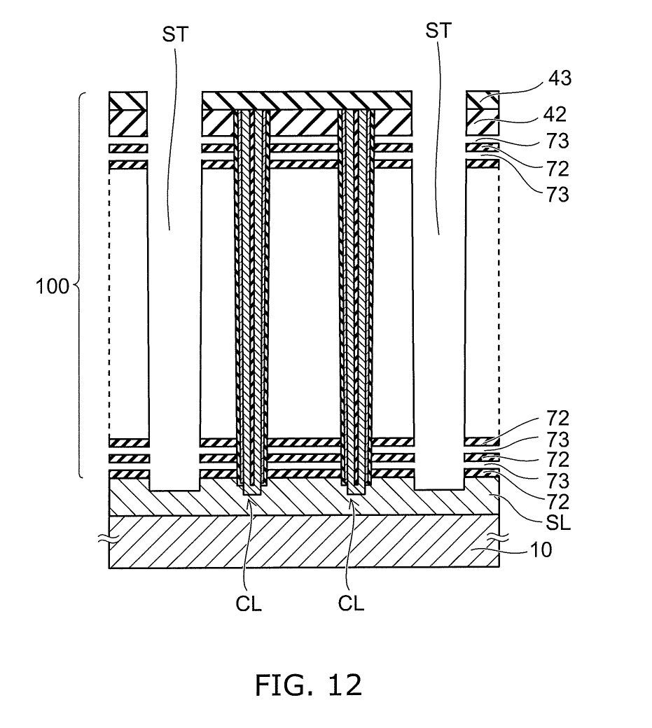

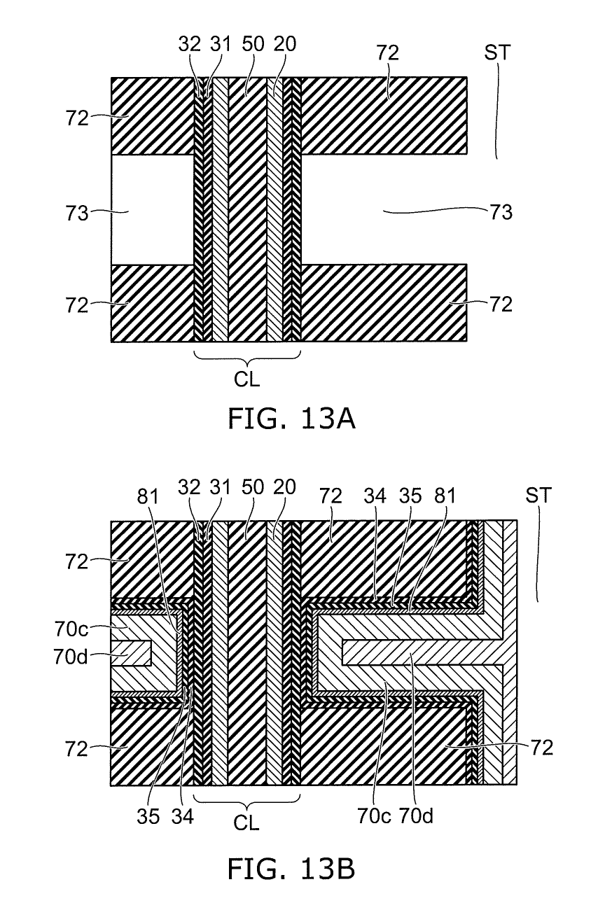

Continuing, the sacrificial layers 71 are removed by an etching gas or an etchant supplied through the slits ST. For example, the sacrificial layers 71 which are silicon nitride layers are removed by a solution including phosphoric acid. The sacrificial layers 71 are removed; and air gaps 73 are formed between the insulating layers 72 adjacent to each other in the stacking direction as shown in FIG. 12 and FIG. 13A. As shown in FIG. 12, the air gap 73 is formed also between the insulating film 42 and the uppermost insulating layer 72.

The multiple insulating layers 72 contact the side surfaces of the multiple columnar portions CL to surround the side surfaces. The multiple insulating layers 72 are supported by such a physical bond with the multiple columnar portions CL; and the air gaps 73 are maintained.

As shown in FIG. 13B, the first blocking film 34, the second blocking film 35, and the barrier metal 81 are formed in order on the inner walls of the air gaps 73. The first blocking film 34, the second blocking film 35, and the barrier metal 81 are formed conformally along the upper surface and the lower surface of the insulating layer 72 and the side surface of the columnar portion CL.

For example, a silicon oxide film is formed by CVD as the first blocking film 34; for example, an aluminum oxide film is formed by CVD as the second blocking film 35; and, for example, a titanium nitride film is formed by CVD as the barrier metal 81. The film formation gases of the CVD are supplied to the air gaps 73 through the slits ST.

The air gaps 73 still remain after forming the barrier metal 81. The electrode layers 70 are filled into the remaining air gaps 73. First, the first conductive film 70c is formed on the surface of the barrier metal 81; then, the second conductive film 70d is formed on the inner side of the first conductive film 70c.

For example, tungsten films are formed as the first conductive film 70c and the second conductive film 70d by CVD (Chemical Vapor Deposition) or ALD (Atomic Layer Deposition) using a gas including tungsten fluoride (WF₆) and hydrogen (H₂). Or, molybdenum films are formed as the first conductive film 70c and the second conductive film 70d by CVD using a gas including molybdenum fluoride (MoF₆) and hydrogen (H₂).

The fluorine concentrations in the first conductive film 70c and in the second conductive film 70d can be controlled by the temperature control in the CVD or the ALD. As the temperature increases, the decomposition of tungsten fluoride (WF₆) is promoted; and fluorine (F) is exhausted outside the wafer through the slits ST and does not remain easily inside the film. Conversely, as the temperature decreases, tungsten fluoride (WF₆) remains easily inside the film without being decomposed. This is similar for the CVD or the ALD forming a molybdenum film using molybdenum fluoride (MoF₆).

For example, in the case where the temperature when forming the first conductive film 70c is set to be higher than the temperature when forming the second conductive film 70d, the fluorine concentration in the first conductive film 70c can be set to be lower than the fluorine concentration in the second conductive film 70d. This sets the resistance of the first conductive film 70c to be lower than the resistance of the second conductive film 70d. Accordingly, in such a case, it is desirable for the volume of the first conductive film 70c to be set to be larger than the volume of the second conductive film 70d.

In CVD or ALD under high-temperature conditions, tungsten fluoride (or molybdenum fluoride) easily becomes a deposit of tungsten (or molybdenum) by decomposing quickly into fluorine and tungsten (or fluorine and molybdenum) when adhering to the surface of the film formation object. Therefore, as the formation of the first conductive film 70c continues in a high-temperature process, tungsten fluoride (or molybdenum fluoride) is deposited easily at the vicinity of the opening of the air gap 73 proximal to the slit ST; and the opening of the air gap 73 is plugged easily by the first conductive film 70c before the air gap 73 is completely filled with a film. In other words, an unfilled portion of the electrode layer 70 inside the air gap 73 occurs easily; and the resistance of the electrode layer 70 increases.

According to the embodiment, after forming the first conductive film 70c in a high-temperature process, the film formation is switched to the second conductive film 70d in a process having a lower temperature. When using lower-temperature conditions, the deposition of tungsten (or molybdenum) does not occur easily due to the decomposition reaction soon after the tungsten fluoride (or the molybdenum fluoride) adheres to the surface of the film formation object; and the space on the inner side of the first conductive film 70c inside the air gap 73 can be filled with the second conductive film 70d before the opening of the air gap 73 is plugged.

At least one of the multiple electrode layers 70 includes the first conductive film 70c and the second conductive film 70d which have different fluorine concentrations each other. That is, at least one of the multiple electrode layers 70 includes portions having different fluorine concentrations along the stacking direction or the thickness direction. Fluorine included in the first conductive film 70c and the second conductive film 70d diffuses in the process accompanying with a heat treatment performed after forming the first conductive film 70c and the second conductive film 70d, and the fluorine concentration near the boundary of the first conductive film 70c and the second conductive film 70d may change continuously. In the case where the second conductive film 70d having the higher fluorine concentration than the first conductive film 70c is formed after forming the first conductive film 70c, the electrode layer 70 can have the profile in which the fluorine concentration increases gradually from the first conductive film 70c toward the center in the thickness direction of the second conductive film 70d.

Also, in the CVD or the ALD forming the second conductive film 70d, for example, nitrogen can be included inside the second conductive film 70d by introducing a gas including the element of nitrogen (e.g., N₂, NH₃, NO, NO₂, N₂O) to the chamber in addition to hydrogen and tungsten fluoride (or molybdenum fluoride). Furthermore, nitrogen can be also included inside the second conductive film 70d by using a metal source gas including N such as W₂(NMe₂)₆, W(NBu)₂(NMe₂)₂, W(CpEt)(CO)₂(NO), Mo(NBu)₂(NMe₂)₂, Mo(NBu)₂(NEt₂)₂. Here, Me is a methyl group, Bu is a Butyl group, Cp is a Cyclopentadienyl group, Et is a Ethyl group.

In these cases, the nitrogen concentration in the second conductive film 70d is higher than the nitrogen concentration in the first conductive film 70c. The fluorine concentration of the second conductive film 70d formed in a process with a lower temperature than that of the first conductive film 70c is higher than the fluorine concentration of the first conductive film 70c; and the tensile stress of the second conductive film 70d may be larger than that of the first conductive film 70c. By adding nitrogen to the second conductive film 70d, the tensile stress of the second conductive film 70d can be reduced or canceled; and the warp of the wafer can be suppressed.

Also, by setting the carbon concentration in the second conductive film 70d to be higher than the carbon concentration in the first conductive film 70c, the tensile stress of the second conductive film 70d can be reduced or canceled; and the warp of the wafer can be suppressed. Or, by setting the oxygen concentration in the second conductive film 70d to be higher than the oxygen concentration in the first conductive film 70c, the tensile stress of the second conductive film 70d can be reduced or canceled; and the warp of the wafer can be suppressed.

For example, in the CVD or the ALD forming the second conductive film 70d, carbon can be included inside the second conductive film 70d by introducing a gas including carbon element (for example, CO, CO₂, CH₄) to the chamber. Furthermore, carbon can be also included inside the second conductive film 70d by using a metal source gas including C such as W(CO)₆, W₂(NMe₂)₆, W(NBu)₂(NMe₂)₂, W(CpEt)(CO)₂(NO), Mo(NBu)₂(NMe₂)₂, Mo(NBu)₂(NEt₂)₂.

For example, in the CVD or the ALD forming the second conductive film 70d, oxygen can be included inside the second conductive film 70d by introducing a gas including an oxygen element (for example, CO, CO₂, NO, NO₂, N₂O) to the chamber. Furthermore, oxygen can be also included inside the second conductive film 70d by using a metal source gas including 0 such as W(CO)₆, WFₓO_{y}, WOCl₄, W(CpEt)(CO)₂(NO).

As shown in FIG. 13B, the first blocking film 34, the second blocking film 35, the barrier metal 81, the first conductive film 70c, and the second conductive film 70d are formed also on the side wall of the slit ST. Among these films, at least the second conductive film 70d, the first conductive film 70c, and the barrier metal 81 which are conductive are removed by etching. The physical connection between the electrode layers 70 of different layers is broken.

Subsequently, the separation portions 60 are formed by forming the insulating films 61 shown in FIG. 2 inside the slits ST.

Although the internal stress of the first conductive film 70c and the internal stress of the second conductive film 70d are caused to be different by the difference between the concentrations of the non-metallic element in the embodiments recited above, the internal stress of the first conductive film 70c and the internal stress of the second conductive film 70d also may be caused to be different by a difference between the crystal grain boundary density of the first conductive film 70c and the crystal grain boundary density of the second conductive film 70d. For example, the crystal grain boundary density can be controlled by controlling the film formation conditions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a stacked body including a plurality of electrode layers stacked with an insulator interposed;
a semiconductor body extending through the stacked body in a stacking direction of the stacked body; and
a charge storage portion provided between the semiconductor body and each of the electrode layers,
at least one of the electrode layers being a tungsten film or a molybdenum film including a portion having different fluorine concentration along the stacking direction.

2. The device according to claim 1, wherein the fluorine concentration in the at least one of the electrode layers is not less than 2×10¹⁷ (atoms/cm³) and not more than 1.5×10²⁰ (atoms/cm³).

3. The device according to claim 1, wherein the at least one of the electrode layers includes a first metal film, and a second metal film provided on an inner side of the first metal film,
the first metal film and the second metal film are tungsten films or molybdenum films,
a fluorine concentration in the first metal film and a fluorine concentration in the second metal film are different.

4. The device according to claim 3, wherein a nitrogen concentration in the first metal film and a nitrogen concentration in the second metal film are different.

5. The device according to claim 3, wherein a carbon concentration in the first metal film and a carbon concentration in the second metal film are different.

6. The device according to claim 3, wherein an oxygen concentration in the first metal film and an oxygen concentration in the second metal film are different.

7. The device according to claim 3, wherein the fluorine concentration in the first metal film is lower than the fluorine concentration in the second metal film.

8. The device according to claim 7, wherein a nitrogen concentration in the first metal film is lower than a nitrogen concentration in the second metal film.

9. The device according to claim 7, wherein a carbon concentration in the first metal film is lower than a carbon concentration in the second metal film.

10. The device according to claim 7, wherein an oxygen concentration in the first metal film is lower than an oxygen concentration in the second metal film.

11. The device according to claim 7, wherein a volume of the first metal film is larger than a volume of the second metal film for at least one of the electrode layers.

12. The device according to claim 3, wherein a lattice constant of the first metal film and a lattice constant of the second metal film are different in an unstrained state.

13. A method for manufacturing a semiconductor device, comprising:
forming a stacked body including a plurality of first layers and a plurality of second layers, the first layers and the second layers including a first layer and a second layer stacked alternately;
forming a columnar portion inside a hole piercing the stacked body, the columnar portion including a semiconductor body extending in a stacking direction of the stacked body;
forming an air gap between the second layers after the forming of the columnar portion by removing the first layers by etching through a slit, the slit piercing the stacked body and dividing the stacked body into a plurality of blocks;
forming a first metal film along an inner wall of the air gap; and
forming a second metal film on an inner side of the first metal film inside the air gap,
tungsten films being formed as the first metal film and the second metal film by CVD or ALD using a gas including tungsten fluoride, or molybdenum films being formed as the first metal film and the second metal film by CVD or ALD using a gas including molybdenum fluoride,
a fluorine concentration in the first metal film and a fluorine concentration in the second metal film being different.

14. The method according to claim 13, wherein a temperature when forming the first metal film and a temperature when forming the second metal film are set to be different.

15. The method according to claim 14, wherein the temperature when forming the second metal film is set to be lower than the temperature when forming the first metal film.

16. The method according to claim 13, wherein a gas including nitrogen is added in the forming of the first metal film or the second metal film.

17. The method according to claim 13, wherein a gas including carbon is added in the forming of the first metal film or the second metal film.

18. The method according to claim 13, wherein a gas including oxygen is added in the forming of the first metal film or the second metal film.

19. The method according to claim 13, wherein
a titanium nitride film is formed along the inner wall of the air gap before the forming of the first metal film, and
the first metal film is grown on the titanium nitride film.

20. A method for manufacturing a semiconductor device, comprising:
forming a stacked body including a plurality of first layers and a plurality of second layers, the first layers and the second layers including a first layer and a second layer stacked alternately;
forming a columnar portion inside a hole piercing the stacked body, the columnar portion including a semiconductor body extending in a stacking direction of the stacked body;
forming an air gap between the second layers after the forming of the columnar portion by removing the first layers by etching through a slit, the slit piercing the stacked body and dividing the stacked body into a plurality of blocks;
forming a first metal film along an inner wall of the air gap; and
forming a second metal film on an inner side of the first metal film inside the air gap,
a tungsten film or a molybdenum film being formed by CVD or ALD as the first metal film and the second metal film,
a temperature when forming the first metal film and a temperature when forming the second metal film being set to be different.
